(19) United States
(12) Patent Application Publication
(10) Pub. No.: US 2022/0036788 A1
(43) Pub. Date: Feb. 3, 2022

(54) SHIFT REGISTER AND METHOD FOR DRIVING THE SAME, GATE DRIVING CIRCUIT, AND DISPLAY APPARATUS

(71) Applicant: BOE TECHNOLOGY GROUP CO., LTD., Beijing (CN)

(72) Inventors: Lubin SHI, Beijing (CN); Xiaohai CHEN, Beijing (CN)

(21) Appl. No.: 17/278,507

(22) PCT Filed: May 9, 2020
(86) PCT No.: PCT/CN2020/089329

§ 371 Date: Mar. 22, 2021

(30) Foreign Application Priority Data
May 13, 2019 (CN) 201910395053.0

(51) Int. Cl. G09G 3/20; G11C 19/28

(52) U.S. Cl. CPC G09G 3/20; G11C 19/28; G09G 2310/0267; G09G 2310/08; G09G 2300/0809; G09G 2310/0286

(57) ABSTRACT

A shift register includes an output sub-circuit and a coupling sub-circuit. The output sub-circuit is coupled to a second clock signal terminal, a pull-up node and a signal output terminal. The output sub-circuit is configured to output a second clock signal received at the second clock signal terminal to the signal output terminal under a control of a voltage of the pull-up node. The coupling sub-circuit is coupled to the second clock signal terminal and a pull-down node. The coupling sub-circuit is configured to couple a voltage of the pull-down node through the second clock signal received at the second clock signal terminal.

### CROSS-REFERENCE TO RELATED APPLICATIONS

This application is a national phase entry under 35 USC 371 of International Patent Application No. PCT/CN2020/089329 filed on May 9, 2020, which claims priority to Chinese Patent Application No, 201910395053.0, filed on May 13, 2019, which are incorporated herein by reference in their entirety.

### TECHNICAL FIELD

The present disclosure relates to the field of display technologies, and in particular, to a shift register and a method for driving the same, a gate driving circuit, and a display apparatus.

### BACKGROUND

As an important component of a display apparatus, a gate driving circuit (also called a scan driving circuit) includes a plurality of stages of cascaded shift registers, and each stage of shift register is coupled to a gate line in a display screen. The gate driving circuit functions to sequentially output switching state voltages of thin film transistor (TFT) devices row by row, i.e., to output scanning signals (also called gate signals) to gate lines in the display screen row by row, thereby turning on a plurality of TFTs coupled to a same gate line in the display screen row by row. In a case where the plurality of TFTs coupled to the gate line are turned on, data signals are input to sub-pixels through data lines, thereby displaying an image.

### SUMMARY

In one aspect, a shift register is provided. The shift register includes an output sub-circuit and a coupling sub-circuit. The output sub-circuit is coupled to a second clock signal terminal, a pull-up node and a signal output terminal. The output sub-circuit is configured to output a second clock signal received at the second clock signal terminal to the signal output terminal under a control of a voltage of the pull-up node. The coupling sub-circuit is coupled to the second clock signal terminal and a pull-down node. The coupling sub-circuit is configured to couple a voltage of the pull-down node through the second clock signal received at the second clock signal terminal.

In some embodiments, the output sub-circuit includes a first transistor and a first capacitor. A control electrode of the first transistor is coupled to the pull-up node, a first electrode of the first transistor is coupled to the second dock signal terminal, and a second electrode of the first transistor is coupled to the signal output terminal. A first electrode of the first capacitor is coupled to the pull-up node, and a second electrode of the first capacitor is coupled to the signal output terminal. The coupling sub-circuit includes a second capacitor. A first electrode of the second capacitor is coupled to the pull-down node, and a second electrode of the second capacitor is coupled to the second dock signal terminal.

In some embodiments, the shift register further includes a first control sub-circuit. The first control sub-circuit is coupled to the signal output terminal, a first voltage signal terminal and the pull-down node. The first control sub-circuit is configured to output a first voltage signal received at the first voltage signal terminal to the pull-down node under a control of a voltage of the signal output terminal.

In some embodiments, the first control sub-circuit includes a second transistor. A control electrode of the second transistor is coupled to the signal output terminal, a first electrode of the second transistor is coupled to the first voltage signal terminal, and a second electrode of the second transistor is coupled to the pull-down node.

In some embodiments, the shift register further includes a second control sub-circuit, a third control sub-circuit, a fourth control sub-circuit and an energy storage sub-circuit. The second control sub-circuit is coupled to the pull-up node, a first voltage signal terminal and the pull-down node. The second control sub-circuit is configured to output a first voltage signal received at the first voltage signal terminal to the pull-down node under the control of the voltage of the pull-up node. Or, the second control sub-circuit is coupled to the pull-up node, a first voltage signal terminal, a second voltage signal terminal and the pull-down node. The second control sub-circuit is configured to output a first voltage signal received at the first voltage signal terminal to the pull-down node in response to the voltage of the pull-up node and a second voltage signal received at the second voltage signal terminal.

The third control sub-circuit is coupled to the pull-up node, the pull-down node and the first voltage signal terminal. The third control sub-circuit is configured to output the first voltage signal received at the first voltage signal terminal to the pull-up node under a control of the voltage of the pull-down node. The fourth control sub-circuit is coupled to a third clock signal terminal, the second voltage signal terminal and the pull-down node. The fourth control sub-circuit is configured to output the second voltage signal received at the second voltage signal terminal to the pull-down node in response to a third clock signal received at the third voltage signal terminal. The energy storage sub-circuit is coupled to the pull-down node and the first voltage signal terminal. The energy storage sub-circuit is configured to perform charging and discharging under the control of the voltage of the pull-down node.

In some embodiments, in a case where the second control sub-circuit is coupled to the pull-up node, the first voltage signal terminal and the pull-down node, and the second control sub-circuit includes a third transistor. A control electrode of the third transistor is coupled to the pull-up node, a first electrode of the third transistor is coupled to the first voltage signal terminal, and a second electrode of the third transistor is coupled to the pull-down node. In a case where the second control sub-circuit is coupled to the pull-up node, the first voltage signal terminal, the second voltage signal terminal and the pull-down node, and the second control sub-circuit includes a third transistor and a fourth transistor. A control electrode of the fourth transistor is coupled to the second voltage signal terminal, a first electrode of the fourth transistor is coupled to the pull-up node, and a second electrode of the fourth transistor is coupled to a control electrode of the third transistor. A first electrode of the third transistor is coupled to the first voltage signal terminal, and a second electrode of the third transistor is coupled to the pull-down node.

The third control sub-circuit includes a fifth transistor. A control electrode of the fifth transistor is coupled to the pull-down node, a first electrode of the fifth transistor is coupled to the first voltage signal terminal, and a second electrode of the fifth transistor is coupled to the pull-up node. The fourth control sub-circuit includes a sixth transistor. A control electrode of the sixth transistor is coupled to the third clock signal terminal, a first electrode of the sixth transistor is coupled to the second voltage signal terminal, and a second electrode of the sixth transistor is coupled to the pull-down node. The energy storage sub-circuit includes a third capacitor. A first electrode of the third capacitor is coupled to the pull-down node, and a second electrode of the third capacitor is coupled to the first voltage signal terminal.

In some embodiments, the shift register further includes a fifth control sub-circuit. The fifth control sub-circuit is coupled to a signal input terminal, the first voltage signal terminal and the pull-down node. The fifth control sub-circuit is configured to output the first voltage signal received at the first voltage signal terminal to the pull-down node in response to a turn-on signal received at the signal input terminal.

In some embodiments, the fifth control sub-circuit includes a seventh transistor. A control electrode of the seventh transistor is coupled to the signal input terminal, a first electrode of the seventh transistor is coupled to the first voltage signal terminal, and a second electrode of the seventh transistor is coupled to the pull-down node.

In some embodiments, the shift register further includes an input sub-circuit and a pull-down sub-circuit. The input sub-circuit is coupled to a signal input terminal, a second voltage signal terminal and the pull-up node. The input sub-circuit is configured to output a second voltage signal received at the second voltage signal terminal to the pull-up node in response to a turn-on signal received at the signal input terminal. Or, the input sub-circuit is coupled to a signal input terminal, a second voltage signal terminal, the pull-up node and a first clock signal terminal. The input sub-circuit is configured to output a second voltage signal received at the second voltage signal terminal to the pull-up node in response to a turn-on signal received at the signal input terminal and a first clock signal received at the first clock signal terminal.

The pull-down sub-circuit is coupled to the pull-down node, a first voltage signal terminal and the signal output terminal. The pull-down sub-circuit is configured to output a first voltage signal received at the first voltage signal terminal to the signal output terminal under a control of the voltage of the pull-down node.

In some embodiments, in a case where the input sub-circuit is coupled to the signal input terminal, the second voltage signal terminal and the pull-up node, and the input sub-circuit includes an eighth transistor. A control electrode of the eighth transistor is coupled to the signal input terminal, a first electrode of the eighth transistor is coupled to the second voltage signal terminal, and a second electrode of the eighth transistor is coupled to the pull-up node. In a case where the input sub-circuit is coupled to the signal input terminal, the second voltage signal terminal, the pull-up node and the first clock signal terminal, and the input sub-circuit includes an eighth transistor and a ninth transistor. A control electrode of the eighth transistor is coupled to the signal input terminal, a first electrode of the eighth transistor is coupled to the second voltage signal terminal, and a second electrode of the eighth transistor is coupled to a first electrode of the ninth transistor. A control electrode of the ninth transistor is coupled to the first clock signal terminal, and a second electrode of the ninth transistor is coupled to the pull-up node.

The pull-down sub-circuit includes a tenth transistor. A control electrode of the tenth transistor is coupled to the pull-down node, a first electrode of the tenth transistor is coupled to the first voltage signal terminal, and a second electrode of the tenth transistor is coupled to the signal output terminal.

In some embodiments, the shift register further includes a first control sub-circuit, a second control sub-circuit, a third control sub-circuit, a fourth control sub-circuit, an energy storage sub-circuit, a fifth control sub-circuit, an input sub-circuit and a pull-down sub-circuit. The output sub-circuit includes a first transistor and a first capacitor. The coupling sub-circuit includes a second capacitor. The first control sub-circuit includes a second transistor. The second control sub-circuit includes a third transistor and a fourth transistor. The third control sub-circuit includes a fifth transistor. The fourth control sub-circuit includes a sixth transistor. The energy storage sub-circuit includes a third capacitor. The fifth control sub-circuit includes a seventh transistor. The input sub-circuit includes an eighth transistor and a ninth transistor. The pull-down sub-circuit includes a tenth transistor.

A control electrode of the first transistor is coupled to the pull-up node, a first electrode of the first transistor is coupled to the second clock signal terminal, and a second electrode of the first transistor is coupled to the signal output terminal. A first electrode of the first capacitor is coupled to the pull-up node, and a second electrode of the first capacitor is coupled to the signal output terminal. A first electrode of the second capacitor is coupled to the pull-down node, and a second electrode of the second capacitor is coupled to the second clock signal terminal. A control electrode of the second transistor is coupled to the signal output terminal, a first electrode of the second transistor is coupled to a first voltage signal terminal, and a second electrode of the second transistor is coupled to the pull-down node. A control electrode of the fourth transistor is coupled to a second voltage signal terminal, a first electrode of the fourth transistor is coupled to the pull-up node, and a second electrode of the fourth transistor is coupled to a control electrode of the third transistor. A first electrode of the third transistor is coupled to the first voltage signal terminal, and a second electrode of the third transistor is coupled to the pull-down node. A control electrode of the fifth transistor is coupled to the pull-down node, a first electrode of the fifth transistor is coupled to the first voltage signal terminal, and a second electrode of the fifth transistor is coupled to the pull-up node. A control electrode of the sixth transistor is coupled to a third clock signal terminal, a first electrode of the sixth transistor is coupled to the second voltage signal terminal, and a second electrode of the sixth transistor is coupled to the pull-down node. A first electrode of the third capacitor is coupled to the pull-down node, and a second electrode of the third capacitor is coupled to the first voltage signal terminal. A control electrode of the seventh transistor is coupled to a signal input terminal, a first electrode of the seventh transistor is coupled to the first voltage signal terminal, and a second electrode of the seventh transistor is coupled to the pull-down node. A control electrode of the eighth transistor is coupled to the signal input terminal, a first electrode of the eighth transistor is coupled to the second voltage signal terminal, and a second electrode of the eighth transistor is coupled to a first electrode of the ninth transistor. A control electrode of the ninth transistor is coupled to a first clock signal terminal, and a second electrode of the ninth transistor is coupled to the pull-up node. A control electrode of the tenth transistor is coupled to the pull-down node, a first electrode of the tenth transistor is coupled to the first voltage signal terminal, and a second electrode of the tenth transistor is coupled to the signal output terminal.

In another aspect, a gate driving circuit is provided. The gate driving circuit includes N stages of cascaded shift registers as described above.

In yet another aspect, a display apparatus is provided. The display apparatus includes the gate driving circuit as described above.

In yet another aspect, a method for driving the shift register as described in any of the above embodiments. The method includes: in an output phase, the output sub-circuit being turned on under the control of the voltage of the pull-up node to output the second clock signal received at the second clock signal terminal as a scanning signal to the signal output terminal; and after the output phase, in a phase in which a voltage of the second clock signal is same as a voltage of the second clock signal in the output phase, the coupling sub-circuit coupling the voltage of the pull-down node through the second clock signal.

### BRIEF DESCRIPTION OF THE DRAWINGS

In order to explain technical solutions of the present disclosure more clearly, accompanying drawings to be used in some embodiments of the present disclosure will be introduced briefly. Obviously, the accompanying drawings to be described below are merely accompanying drawings of some embodiments of the present disclosure, and a person of ordinary skill in the art can obtain other drawings according to these drawings. In addition, accompanying drawings in the following description may be regarded as schematic diagrams, which are not limitations on an actual size of a product, an actual process of a method and an actual timing of a signal involved in the embodiments of the present disclosure.

FIG. 1 is a structural diagram of a display panel, in accordance with some embodiments of the present disclosure;

FIG. 2 is another structural diagram of a display panel, in accordance with some embodiments of the present disclosure;

FIG. 3 is a structural diagram of a shift register, in accordance with some embodiments of the present disclosure;

FIG. 4 is another structural diagram of a shift register, in accordance with some embodiments of the present disclosure;

FIG. 5 is a structural diagram of a gate driving circuit, in accordance with some embodiments of the present disclosure; and

FIG. 6 is a timing control diagram corresponding to the shift register in FIG. 4, in accordance with some embodiments of the present disclosure.

### DETAILED DESCRIPTION

Technical solutions in some embodiments of the present disclosure will be described clearly and completely with reference to accompanying drawings. Obviously, the described embodiments are merely some but not all embodiments of the present disclosure. All other embodiments obtained on a basis of the embodiments of the present disclosure by a person of ordinary skill in the art shall be included in the protection scope of the present disclosure.

Unless the context requires otherwise, throughout the description and claims, the term “comprise” and other forms such as the third-person singular form “comprises” and the present participle form “comprising” are interpreted as an open and inclusive meaning, i.e., “including, but not limited to.” In the description of the specification, the terms such as “one embodiment”, “some embodiments”, “exemplary embodiments”, “an example”, and “specific examples” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or examples(s). In addition, the specific features, structures, materials or characteristics may be included in any one or more embodiments or examples in any suitable manner.

In the following, the terms “first” and “second” are only used for description purposes, and are not to be construed as indicating or implying relative importance or implicitly indicating the number of indicated technical features. Thus, a feature defined by “first” or “second” may explicitly or implicitly include one or more of the features. In the description of the embodiments of the present disclosure, the term “a plurality of/the plurality of” means two or more unless otherwise specified.

In the description of some embodiments, the expressions such as “coupled” and “connected” and their extensions may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The use of “applicable to” or “configured to” herein means an open and inclusive expression, which does not exclude devices applicable to or configured to perform additional tasks or steps.

A pull-up node (PU) and a pull-down node (PD) are provided in a shift register in a gate driving circuit. In a working process of the gate driving circuit, the shift register controls the output of scanning signals by controlling potentials of the pull-up node (PU) and the pull-down node (PD). However, in part of phases in a period after the shift register outputs the scanning signals and before an arrival of a next image frame, since the potentials of the pull-up node (PU) and the pull-down node (PD) are not effectively controlled by an actual signal terminal, the potentials of the pull-up node (PU) and the pull-down node (PD) only maintain states in a previous phase. In this way, it may result in a phase of the pull-up node (PU) and the pull-down node (PD) (especially the PD) being in a floating (or suspended) state, so that the pull-up node (PU) and the pull-down node (PD) are easily affected by peripheral circuits (such as peripheral parasitic capacitors), which results in changes of the potentials of the pull-up node (PU) and the pull-down node (PD); thereby causing an unstable output of the scanning signals.

On this basis, some embodiments of the present disclosure provide a shift register and a method for driving the same, a gate driving circuit and a display apparatus, which are respectively introduced below.

Embodiments of the present disclosure provide a display apparatus, and the display apparatus may be any apparatus that displays images, whether moving (e.g., videos) or stationary (e.g., still images). More specifically, it is contemplated that the embodiments may be implemented in, or associated with, a variety of electronic apparatuses. The variety of electronic apparatuses are, for example (but not limited to), mobile phones, wireless apparatuses, personal data assistants (PDAs), hand-held or portable computers, GPS receivers/navigators, cameras, MP4 video players, camcorders, game consoles, watches, clocks, calculators, TV monitors, panel displays, computer monitors, auto monitors (e.g., odometer displays), navigators, cockpit controllers and/or displays, camera view displays (e.g., rear-view camera displays in vehicles), electronic photos, electronic billboards or signs, projectors, architectural structures, packaging s, and aesthetic structures (e.g., displays for displaying an image of a piece of jewelry), etc.

The display apparatus includes a frame, and a display panel, a circuit board, a display driver integrated circuit (IC) and other electronic accessories that are disposed in the frame.

The display panel may be a liquid crystal display (LCD) panel, an organic light-emitting diode (OLED) display panel, a quantum dot light-emitting diode (QLED) display panel, a micro light-emitting diode (Micro LED) display panel, etc., which are not specifically limited in the present disclosure.

The present disclosure is described in the following embodiments of the present disclosure by taking an example in which the display panel is the OLED display panel.

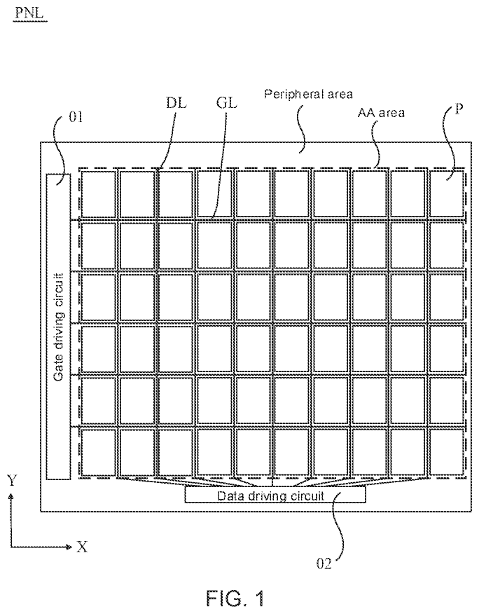

As shown in FIG. 1, the display panel PNL includes an active area (AA area, also called an effective display area) and a peripheral area arranged around the AA area.

The display panel PNL includes sub-pixels P of a plurality of colors in the AA area. The sub-pixels P of the plurality of colors include at least sub-pixels of a first color, sub-pixels of a second color and sub-pixels of a third color. The first, second and third colors are three primary colors (e.g., red, green and blue, respectively).

For convenience of description, the plurality of sub-pixels P are illustrated by taking an example in which the plurality of sub-pixels P are arranged in a matrix form. In this case, as shown in FIG. 1, the sub-pixels P arranged in a row in a horizontal direction X are referred to as sub-pixels in a same row. The sub-pixels P arranged in a column in a vertical direction Y are referred to as sub-pixels in a same column.

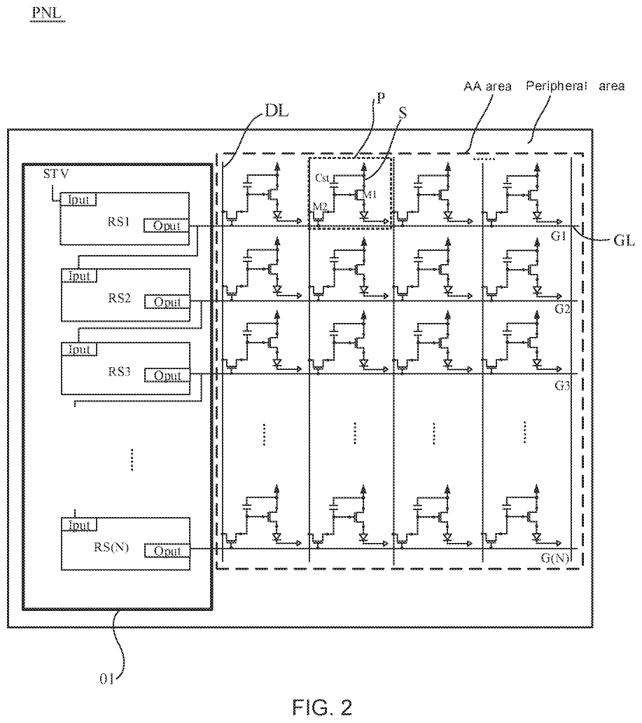

As shown in FIG. 2, in the OLE© display panel PNL, a pixel circuit (also referred to as a pixel driving circuit) S is provided in each sub-pixel P, and the pixel circuit S includes transistors and a capacitor. FIG. 2 only schematically illustrates an example in which the pixel circuit S is of a 2T1C (a driving transistor M1, a switching transistor M2 and a capacitor Cst) structure. A specific structure of the pixel circuit in the embodiments of the present disclosure is not limited, and for example, 3T1C, 4T1C and other structures may also be used. As shown in FIG. 2, in the display panel PNL, control electrodes of the switching transistors M2 of the pixel circuits S in a same row are coupled to a same gate line (GL), and first electrodes (e.g., sources) of the switching transistors M2 of the pixel circuits S in a same column are coupled to a same data line (DL).

Referring to FIG. 1, a gate driving circuit 01 and a data driving circuit 02 are provided in the peripheral area of the display panel PNL. In some embodiments, the gate driving circuit 01 may be disposed at a side of the AA area in an extension direction of the gate lines GL_ and the data driving circuit 02 may be disposed at a side of the AA area in an extension direction of the data lines DL, so as to drive the pixel circuits S in the display panel to display an image.

In some embodiments, the gate driving circuit 01 may be a gate driving IC. In some other embodiments, the gate driving circuit 01 may be a gate driver on array (GOA) circuit. That is, the gate driving circuit 01 is directly integrated into an array substrate of the display panel PNL. Setting the gate driving circuit 01 as the GOA circuit may reduce the manufacturing cost of the display panel, and may narrow the border width of the display apparatus. The following embodiments are all illustrated by taking an example in which the gate driving circuit 01 is the GOA circuit.

It will be noted that FIGS. 1 and 2 only schematically illustrate an example in which the gate drive circuit 01 is provided on a single side of the peripheral area of the display panel PNL, and the gate lines GL are driven row by row from the single side, i.e., driven in a single-sided manner. In some other embodiments, the gate driving circuits may be respectively disposed on both sides of the peripheral area of the display panel PNL in the extension direction of the gate lines GL, and the gate lines GL are driven by the two gate driving circuits row by row from the both sides simultaneously, i.e., driven in a double-sided manner. In some other embodiments, the gate driving circuits may be respectively disposed on the both sides of the peripheral area of the display panel PNL in the extension direction of the gate lines GL, and the gate lines GL are driven by the two gate driving circuits row by row from the both sides alternately, i.e., driven in a crossed manner. The following embodiments of the present disclosure are all described by taking the single-sided driving as an example.

As shown in FIG. 2, the gate driving circuit 01 includes N stages of cascaded shift registers (RS1, RS2, . . . , RS(N)), and in this case, the display panel PNL includes N gate lines (G1, G2, . . . , G(N)) coupled to the N stages of cascaded shift registers (RS1, RS2, . . . , RS(N)) in one-to-one correspondence, Here, N is a positive integer.

In addition, as shown in FIG. 2, a signal input terminal Input (abbreviated as Iput in the drawings and the following contents), and a signal output terminal Output (abbreviated as Oput in the drawings and the following contents) are further provided in the shift register (RS1, RS2, . . . , RS(N)) of the gate driving circuit 01. Circuit structures of all stages of shift registers in the gate driving circuit 01 may be the same.

On this basis, in the gate driving circuit 01, the signal input terminal(s) Iput of previous one or more stages of shift register(s) are coupled to a start signal terminal STV. Except the shift register(s) coupled to the start signal terminal STV, a signal output terminal Oput of a previous stage of shift register is coupled to a signal input terminal Iput of a next stage of shift register. Here, the previous stage of shift register and the next stage of shift register may be or may not be shift registers in adjacent stages.

For example, as shown in FIG. 2, in the gate driving circuit 01, a signal input terminal put of a first stage of shift register RS1 may be coupled to the start signal terminal STV, and a signal output terminal Oput of an i-th stage of shift register RS(i) is coupled to a signal input terminal Iput of an (i+1)-th stage of shift register RS(i+1). Here, i is a positive integer greater than or equal to 2 and less than or equal to (N−1).

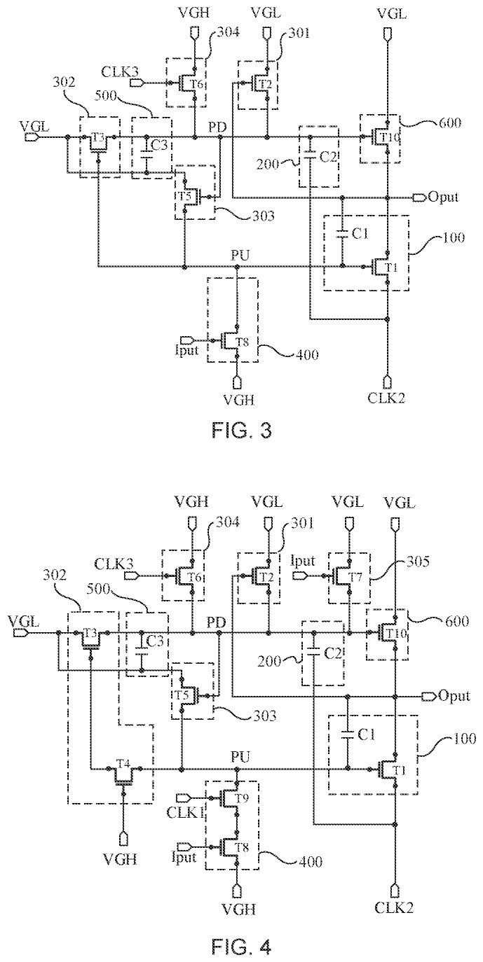

In addition, it will be understood by those skilled in the art that, for the shift register itself, as shown in FIG. 3, a pull-up node PU and a pull-down node PD are provided in the shift register, and the normal output of the shift register is realized by controlling potentials of the pull-up node PU and the pull-down node PD. In the working process of the shift register, the potentials of the pull-up node PU and the pull-down node PD are always a group of reversed potentials. For example, in a case where the pull-up node PU is at a high potential, the pull-down node PD is at a low potential, and in a case where the pull-up node PU is at a low potential, the pull-down node PD is at a high potential.

On this basis, as shown in FIG. 3 or FIG. 4, the shift register in some embodiments of the present disclosure includes an output sub-circuit 100 and a coupling sub-circuit 200.

The output sub-circuit 100 is coupled to a second dock signal terminal CLK2, the pull-up node PU and the signal output terminal Oput. The output sub-circuit 100 is configured to output a second clock signal received at the second clock signal terminal CLK2 to the signal output terminal Oput under a control of a voltage of the pull-up node PU.

The coupling sub-circuit 200 is coupled to the second clock signal terminal CLK2 and the pull-down node PD. The coupling sub-circuit 200 is configured to couple a voltage of the pull-down node PD through the second clock signal received at the second clock signal terminal CLK2.

For example, as shown in FIG. 3 or FIG. 4, in some embodiments, the output sub-circuit 100 includes a first transistor T1 and a first capacitor C1.

A control electrode of the first transistor T1 is coupled to the pull-up node PU, a first electrode of the first transistor T1 is coupled to the second clock signal terminal CLK2, and a second electrode of the first transistor T1 is coupled to the signal output terminal Oput. The first transistor T1 is configured to be turned on under the control of the voltage of the pull-up node PU to output the second clock signal received at the second clock signal terminal CLK2 to the signal output terminal Oput.

A first electrode of the first capacitor C1 is coupled to the pull-up node PU, and a second electrode of the first capacitor C1 is coupled to the signal output terminal Oput. The first capacitor C1 is configured to store the voltage of the pull-up node PU and discharge to the pull-up node PU, so that the potential of the pull-up node PU is maintained at a high potential.

For example, as shown in FIG. 3 or FIG. 4, in some embodiments, the coupling sub-circuit 200 may include a second capacitor C2. A first electrode of the second capacitor C2 is coupled to the pull-down node PD, and a second electrode of the second capacitor C2 is coupled to the second clock signal terminal CLK2. The second capacitor C2 is configured to couple the voltage of the pull-down node PD through the second clock signal received at the second clock signal terminal CLK2 according to a bootstrap effect of the capacitor.

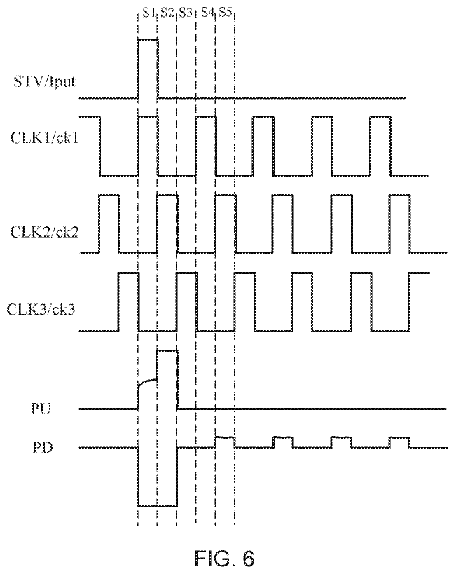

In summary, in the shift register in the embodiments of the disclosure, the output sub-circuit 100 can output the second clock signal received at the second clock signal terminal CLK2 as a scanning signal (in this case, a level of the second clock signal is a high level) to the signal output terminal Oput under the control of the voltage of the pull-up node PU. Also, in a period after the scanning signal is output and before an arrival of a next frame, a potential of the second clock signal transmitted by the second clock signal terminal CLK2 changes periodically, and in a phase in which the potential of the second clock signal is the same as the potential thereof in a phase in which the scanning signal is output (i.e., in a phase in which the level of the second clock signal is a high level as shown in FIG. 6), the coupling sub-circuit 200 couples the voltage of the pull-down node PD through the second clock signal received at the second clock signal terminal CLK2, thereby stabilizing the voltage of the pull-down node PD. Therefore, the phase in which the pull-up node PU and the pull-down node PD are in the suspended state after the shift register have output the scanning signal is shortened, and thus a possibility of potential changes of the pull-up node PU and the pull-down node PD caused by an influence of peripheral circuits (e.g., peripheral parasitic capacitors) is reduced, and an output stability of the shift register is improved consequently.

On this basis, in order to further improve the output stability of the shift register, in some embodiments, as shown in FIG. 3 or FIG. 4, the shift register may further include a first control sub-circuit 301. The first control sub circuit 301 is coupled to the signal output terminal Oput, a first voltage signal terminal VGL and the pull-down node PD. The first control sub-circuit 301 is configured to output a first voltage signal received at the first voltage signal terminal VGL to the pull-down node PD under a control of a voltage of the signal output terminal Oput. For example, the first voltage signal is a low level signal, thereby pulling down the potential of the pull-down node PD.

For example, as shown in FIG. 3 or FIG. 4, the first control sub-circuit 301 includes a second transistor T2. A control electrode of the second transistor T2 is coupled to the signal output terminal ° put, a first electrode of the second transistor T2 is coupled to the first voltage signal terminal VGL, and a second electrode of the second transistor T2 is coupled to the pull-down node PD. In this way, when the signal output terminal Oput outputs the scanning signal, the second transistor T2 is turned on under a control of the scanning signal to transmit the first voltage signal (a voltage of the first voltage signal is a low level voltage) received at the first voltage signal terminal VGL to the pull-down node PD, thereby ensuring that the potential of the pull-down node PD is pulled down, and the potential of the pull-down node PD is low in the output phase of the scanning signal (in this case, the potential of the pull-up node PU is high).

In addition, it will be understood by those skilled in the art that, for the shift register itself, on the basis of including the output sub-circuit 100 and the coupling sub-circuit 200, the shift register further includes other relevant control circuits coupled to the pull-up node PU and the pull-down node PD, which is not specifically limited in the embodiments of the present disclosure, and in practice, an appropriate relevant circuit may be selectively provided according to needs.

For example, embodiments of the present disclosure provide a specific shift register. As shown in FIG. 3 or FIG. 4, on the basis of including the output sub-circuit 100 and the coupling sub-circuit 200, the shift register further includes a second control sub-circuit 302, a third control sub-circuit 303, a fourth control sub-circuit 304 and an energy storage sub-circuit 500.

In some embodiments, as shown in FIG. 3, the second control sub-circuit 302 is coupled to the pull-up node PU, the first voltage signal terminal VGL and the pull-down node PD. The second control sub-circuit 302 is configured to output the first voltage signal received at the first voltage signal terminal VGL to the pull-down node PD under the control of the voltage of the pull-up node PU.

For example, as shown in FIG. 3, the second control sub-circuit 302 includes a third transistor T3. A control electrode of the third transistor T3 is coupled to the pull-up node PU, a first electrode of the third transistor T3 is coupled to the first voltage signal terminal VGL, and a second electrode of the third transistor T3 is coupled to the pull-down node PD, The third transistor T3 is configured to be turned on under the control of the voltage of the pull-up node PU to output the first voltage signal received at the first voltage signal terminal VGL to the pull-down node PD.

In some other embodiments, as shown in FIG. 4, the second control sub-circuit 302 is coupled to the pull-up node PU, the first voltage signal terminal VGL, a second voltage signal terminal VGH and the pull-down node PD. The second control sub-circuit 302 is configured to output the first voltage signal received at the first voltage signal terminal VGL to the pull-down node PD in response to the voltage of the pull-up node PU and a second voltage signal received at the second voltage signal terminal VGH.

For example, as shown in FIG. 4, the second control sub-circuit 302 may include a third transistor T3 and a fourth transistor T4.

A control electrode of the fourth transistor T4 is coupled to the second voltage signal terminal VGH, a first electrode of the fourth transistor T4 is coupled to the pull-up node PU, and a second electrode of the fourth transistor T4 is coupled to a control electrode of the third transistor T3. The fourth transistor T4 is configured to be turned on under a control of the second voltage signal transmitted by the second voltage signal terminal VGH to output the voltage of the pull-up node PU to the control electrode of the third transistor T3.

A first electrode of the third transistor T3 is coupled to the first voltage signal terminal VGL, and a second electrode of the third transistor T3 is coupled to the pull-down node PD. The third transistor T3 is configured to be turned on under the control of the voltage of the pull-up node PU to output the first voltage signal received at the first voltage signal terminal VGL to the pull-down node PD.

In some embodiments, as shown in FIG. 3 or FIG. 4, the third control sub-circuit 303 is coupled to the pull-up node PU, the pull-down node PD and the first voltage signal terminal VGL. The third control sub-circuit 303 is configured to output the first voltage signal received at the first voltage signal terminal VGL to the pull-up node PU under a control of the voltage of the pull-down node PD.

For example, as shown in FIG. 3 or FIG. 4, the third control sub-circuit 303 may include a fifth transistor T5. A control electrode of the fifth transistor T5 is coupled to the pull-down node PD, a first electrode of the fifth transistor T5 is coupled to the first voltage signal terminal VGL, and a second electrode of the fifth transistor T5 is coupled to the pull-up node PU. The fifth transistor T5 is configured to be turned on under the control of the voltage of the pull-down node PD to output the first voltage signal received at the first voltage signal terminal VGL to the pull-up node PU.

In some embodiments, as shown in FIG. 3 or FIG. 4, the fourth control sub-circuit 304 is coupled to a third clock signal terminal CLK3, the second voltage signal terminal VGH and the pull-down node PD. The fourth control sub-circuit 304 is configured to output the second voltage signal received at the second voltage signal terminal VGH to the pull-down node PD in response to a third clock signal received at the third clock signal terminal CLK3. For example, the second voltage signal is a high-level signal, and the potential of the pull-down node PD is pulled up.

For example, as shown in FIG. 3 or FIG. 4, the fourth control sub-circuit 304 may include a sixth transistor T6. A control electrode of the sixth transistor T6 is coupled to the third dock signal terminal CLK3, a first electrode of the sixth transistor T6 is coupled to the second voltage signal terminal VGH, and a second electrode of the sixth transistor T6 is coupled to the pull-down node PD. The sixth transistor T6 is configured to be turned on under a control of the third clock signal to output the second voltage signal received at the second voltage signal terminal VGH to the pull-down node PD.

In some embodiments, as shown in FIG. 3 or FIG. 4, the energy storage sub-circuit 500 is coupled to the pull-down node PD and the first voltage signal terminal VGL. The energy storage sub-circuit 500 is configured to perform charging and discharging under the control of the voltage of the pull-down node PD.

For example, as shown in FIG. 3 or FIG. 4, the energy storage sub-circuit may include a third capacitor C3. A first electrode of the third capacitor C3 is coupled to the pull-down node PD, and a second electrode of the third capacitor C3 is coupled to the first voltage signal terminal VGL.

On this basis, in order to further improve the output stability of the shift register, in some embodiments, as shown in FIG. 4, the shift register may further include a fifth control sub-circuit 305. The fifth control sub circuit 305 is coupled to the signal input terminal Iput, the first voltage signal terminal VGL and the pull-down node PD. The fifth control sub-circuit 305 is configured to output the first voltage signal received at the first voltage signal terminal VGL to the pull-down node PD in response to a turn-on signal received at the signal input terminal Iput.

For example, as shown in FIG. 4, the fifth control sub-circuit may include a seventh transistor T7. A control electrode of the seventh transistor T7 is coupled to the signal input terminal Iput, a first electrode of the seventh transistor T7 is coupled to the first voltage signal terminal VGL, and a second electrode of the seventh transistor T7 is coupled to the pull-down node PD. The seventh transistor T7 is configured to be turned on under a control of the turn-on signal to output the first voltage signal received at the first voltage signal terminal VGL to the pull-down node PD.

In this way, when the signal input terminal Iput receives the turn-on signal, the seventh transistor T7 is turned on under the control of the turn-on signal, so that the first voltage signal received at the first voltage signal terminal VGL is output to the pull-down node PD, thereby ensuring that the pull-down node PD is at a low potential in a phase in which a level of the turn-on signal is a high level (in this case, the pull-up node PU is at a high potential).

In some embodiments, as shown in FIGS. 3 and 4, the shift register in the embodiments of the present disclosure further includes an input sub-circuit 400 and a pull-down sub-circuit 600 on the basis of including the above-mentioned sub-circuits.

In some embodiments, as shown in FIG. 3, the input sub-circuit 400 is coupled to the signal input terminal Iput, the second voltage signal terminal VGH and the pull-up node PU. The input sub-circuit 400 is configured to output the second voltage signal received at the second voltage signal terminal VGH to the pull-up node PU in response to the turn-on signal received at the signal input terminal Iput.

For example, as shown in FIG. 3, the input sub-circuit 400 may include an eighth transistor T8. A control electrode of the eighth transistor T8 is coupled to the signal input terminal Iput, a first electrode of the eighth transistor T8 is coupled to the second voltage signal terminal VGH, and a second electrode of the eighth transistor T8 is coupled to the pull-up node PU. The eighth transistor T8 is configured to be turned on under the control of the turn-on signal to output the second voltage signal received at the second voltage signal terminal VGH to the pull-up node PU.

In some other embodiments, as shown in FIG. 4, the input sub-circuit 400 is coupled to the signal input terminal Iput, the second voltage signal terminal VGH, the pull-up node PU and a first clock signal terminal CLK1. The input sub-circuit 400 is configured to output the second voltage signal received at the second voltage signal terminal VGH to the pull-up node PU in response to the turn-on signal received at the signal input terminal Iput and a first clock signal received at the first clock signal terminal CLK1.

For example, as shown in FIG. 4, the input sub-circuit 400 may include an eighth transistor T8 and a ninth transistor T9.

A control electrode of the eighth transistor T8 is coupled to the signal input terminal Iput, a first electrode of the eighth transistor T8 is coupled to the second voltage signal terminal VGH, and a second electrode of the eighth transistor T8 is coupled to a first electrode of the ninth transistor T9. The eighth transistor T8 is configured to be turned on under the control of the turn-on signal transmitted by the signal input terminal Iput to output the second voltage signal received at the second voltage signal terminal VGH to the first electrode of the ninth transistor T9.

A control electrode of the ninth transistor T9 is coupled to the first clock signal terminal CLK1, and a second electrode of the ninth transistor T9 is coupled to the pull-up node PU. The ninth transistor T9 is configured to be turned on under a control of the first clock signal transmitted by the first dock signal terminal CLK1 to output the second voltage signal to the pull-up node PU.

In some embodiments, as shown in FIG. 3 or FIG. 4, the pull-down sub-circuit 600 is coupled to the pull-down node PD, the first voltage signal terminal VGL and the signal output terminal Oput. The pull-down sub-circuit 600 is configured to output the first voltage signal received at the first voltage signal terminal VGL to the signal output terminal Oput under the control of the voltage of the pull-down node PD.

For example, as shown in FIG. 3 or FIG. 4, the pull-down sub-circuit 600 may include a tenth transistor T10. A control electrode of the tenth transistor T10 is coupled to the pull-down node PD, a first electrode of the tenth transistor T10 is coupled to the first voltage signal terminal VGL, and a second electrode of the tenth transistor T10 is coupled to the signal output terminal Oput. The tenth transistor T10 is configured to be turned on under the control of the voltage of the pull-down node PD to output the first voltage signal received at the first voltage signal terminal VGL to the signal output terminal Oput.

Referring to FIG. 4 again, the structure of the shift register in some embodiments of the present disclosure will be introduced as a whole and exemplarily below.

The shift register includes the output sub-circuit 100, the coupling sub-circuit 200, the first control sub-circuit 301, the second control sub-circuit 302, the third control sub-circuit 303, the fourth control sub-circuit 304, the energy storage sub-circuit 500, the fifth control sub-circuit 305, the input sub-circuit 400 and the pull-down sub-circuit 600.

The output sub-circuit 100 includes the first transistor T1 and the first capacitor C1 The coupling sub-circuit 200 includes the second capacitor C2. The first control sub-circuit 301 includes the second transistor T2. The second control sub-circuit 302 includes the third transistor T3 and the fourth transistor T4. The third control sub-circuit 303 includes the fifth transistor T5. The fourth control sub-circuit 304 includes the sixth transistor T6, The energy storage sub-circuit 500 includes the third capacitor C3. The fifth control sub-circuit 305 includes the seventh transistor T7. The input sub-circuit 400 includes the eighth transistor T8 and the ninth transistor T9. The pull-down sub-circuit 600 includes the tenth transistor T10.

The control electrode of the first transistor T1 is coupled to the pull-up node PU, the first electrode of the first transistor T1 is coupled to the second clock signal terminal CLK2, and the second electrode of the first transistor T1 is coupled to the signal output terminal Oput. The first transistor T1 is configured to be turned on under the control of the voltage of the pull-up node PU to output the second clock signal received at the second clock signal terminal CLK2 to the signal output terminal Oput.

The first electrode of the first capacitor C1 is coupled to the pull-up node PU, and the second electrode of the first capacitor C1 is coupled to the signal output terminal Oput. The first capacitor C1 is configured to store the voltage of the pull-up node PU and discharge to the pull-up node PU, so that the potential of the pull-up node PU is maintained at a high potential.

The first electrode of the second capacitor C2 is coupled to the pull-down node PD, and the second electrode of the second capacitor C2 is coupled to the second clock signal terminal CLK2. The coupling sub-circuit 200 is configured to couple the voltage of the pull-down node PD through the second clock signal received at the second clock signal terminal CLK2 according to the bootstrap effect of the capacitor.

The control electrode of the second transistor T2 is coupled to the signal output terminal ° put, the first electrode of the second transistor T2 is coupled to the first voltage signal terminal VGL, and the second electrode of the second transistor T2 is coupled to the pull-down node PD. The second transistor T2 is configured to be turned on under the control of the voltage of the signal output terminal Oput to output the first voltage signal received at the first voltage signal terminal VGL to the pull-down node PD.

The control electrode of the fourth transistor T4 is coupled to the second voltage signal terminal VGH, the first electrode of the fourth transistor T4 is coupled to the pull-up node PU, and the second electrode of the fourth transistor T4 is coupled to the control electrode of the third transistor T3. The fourth transistor T4 is configured to be turned on under the control of the second voltage signal transmitted by the second voltage signal terminal VGH to output the voltage of the pull-up node PU to the control electrode of the third transistor T3.

The first electrode of the third transistor T3 is coupled to the first voltage signal terminal VGL, and the second electrode of the third transistor T3 is coupled to the pull-down node PD. The third transistor T3 is configured to be turned on under the control of the voltage of the pull-up node PU to output the first voltage signal received at the first voltage signal terminal VGL to the pull-down node PD.

The control electrode of the fifth transistor T5 is coupled to the pull-down node PD, the first electrode of the fifth transistor T5 is coupled to the first voltage signal terminal VGL, and the second electrode of the fifth transistor T5 is coupled to the pull-up node PU. The fifth transistor T5 is configured to be turned on under the control of the voltage of the pull-down node PD to output the first voltage signal received at the first voltage signal terminal VGL to the pull-up node PU.

The control electrode of the sixth transistor T6 is coupled to the third clock signal terminal CLK3, the first electrode of the sixth transistor T6 is coupled to the second voltage signal terminal VGH, and the second electrode of the sixth transistor T6 is coupled to the pull-down node PD. The sixth transistor T6 is configured to be turned on under the control of the third clock signal to output the second voltage signal received at the second voltage signal terminal VGH to the pull-down node PD.

The control electrode of the seventh transistor T7 is coupled to the signal input terminal Iput, the first electrode of the seventh transistor T7 is coupled to the first voltage signal terminal VGL, and the second electrode of the seventh transistor T7 is coupled to the pull-down node PD. The seventh transistor T7 is configured to be turned on under the control of the turn-on signal received at the signal input terminal put to output the first voltage signal received at the first voltage signal terminal VGL to the pull-down node PD.

The control electrode of the eighth transistor T8 is coupled to the signal input terminal Iput, the first electrode of the eighth transistor T8 is coupled to the second voltage signal terminal VGH, and the second electrode of the eighth transistor T8 is coupled to the first electrode of the ninth transistor T9. The eighth transistor T8 is configured to be turned on under the control of the turn-on signal transmitted by the signal input terminal Iput to output the second voltage signal received at the second voltage signal terminal VGH to the first electrode of the ninth transistor T9.

The control electrode of the ninth transistor T9 is coupled to the first clock signal terminal CLK1, and the second electrode of the ninth transistor T9 is coupled to the pull-up node PU. The ninth transistor T9 is configured to be turned on under the control of the first clock signal transmitted by the first clock signal terminal CLK1 to output the second voltage signal to the pull-up node PU.

The control electrode of the tenth transistor T10 is coupled to the pull-down node PD, the first electrode of the tenth transistor T10 is coupled to the first voltage signal terminal VGL, and the second electrode of the tenth transistor T10 is coupled to the signal output terminal Oput. The tenth transistor T10 is configured to be turned on under the control of the voltage of the pull-down node PD to output the first voltage signal received at the first voltage signal terminal VGL to the signal output terminal Oput.

The first electrode of the third capacitor C3 is coupled to the pull-down node PD, and the second electrode of the third capacitor C3 is coupled to the first voltage signal terminal VGL.

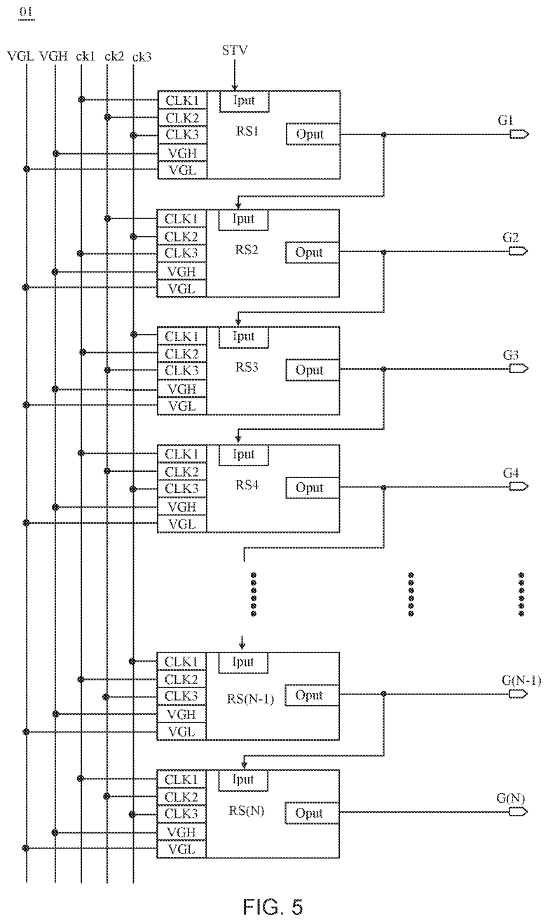

For the gate driving circuit 01 formed by cascading the shift registers shown in FIG. 4, in some embodiments, as shown in FIG. 5 (FIG. 5 illustrates an example in which N is an integer multiple of 3, but the embodiments of the present disclosure are not limited thereto). In the gate driving circuit 01:

the first clock signal terminal CLK1, the second clock signal terminal CLK2 and the third clock signal terminal CLK3 of a (3t+1)-th stage of shift register (RS1, RS4, RS7 . . . ) are respectively and sequentially coupled to a first system clock signal terminal ck1, a second system clock signal terminal ck2 and a third system clock signal terminal ck3;

the first clock signal terminal CLK1, the second clock signal terminal CLK2 and the third clock signal terminal CLK3 of a (3t+2)-th stage of shift register (RS2, RS5, RS8 . . . ) are respectively and sequentially coupled to the second system clock signal terminal ck2, the third system clock signal terminal ck3 and the first system clock signal terminal ck1;

the first clock signal terminal CLK1, the second clock signal terminal CLK2 and the third clock signal terminal CLK3 of a (3t+3)-th stage of shift register (RS3, RS6, RS9 . . . ) are respectively and sequentially coupled to the third system clock signal terminal ck3, the first system clock signal terminal ck1 and the second system clock signal terminal ck2, here, (3t+3) is less than or equal to N, and t is a variable of a natural number.

On this basis, it will be noted that FIGS. 3 and 4 only exemplarily illustrate two specific circuit structures of the shift register in the embodiments of the present disclosure. Structures of the sub-circuits other than the output sub-circuit 100 and the coupling sub-circuit 200 are not specifically limited in the embodiments of the present disclosure, and the disclosure of any shift register that at least adopts the output sub-circuit 100 and the coupling sub-circuit 200 in the embodiments of the present disclosure shall be included in the protection scope of the present disclosure.

On this basis, some embodiments of the present disclosure further provide a method for driving a shift register. The method for driving the shift register in the embodiments of the present disclosure in an image frame is described below by taking the first stage of shift register RS1 in the gate driving circuit 01 (formed by cascading the shift registers in FIG. 4) shown in FIG. 5 as an example, and by combining with the timing control diagram in FIG. 6.

Referring to FIGS. 4 to 6, for the first stage of shift register RS1, the signal input terminal Iput thereof is coupled to the start signal terminal STV, the first clock signal terminal CLK1 thereof is coupled to the first system clock signal terminal ck1, the second clock signal terminal CLK2 thereof is coupled to the second system clock signal terminal ck2, and the third clock signal terminal CLK3 thereof is coupled to the third system clock signal terminal ck3. The method for driving the first stage of shift register RS1 in an image frame includes following phases.

In a first phase S1 (also referred to as an input phase):

the turn-on signal (at a high level in this case) is input to the signal input terminal Iput (through the start signal terminal STV). A level of the first clock signal transmitted by the first clock signal terminal CLK1 is a high level, a level of the second clock signal transmitted by the second clock signal terminal CLK2 is a low level, and a level of the third clock signal transmitted by the third clock signal terminal CLK3 is a low level, Take the first voltage signal transmitted by the first voltage signal terminal VGL being a low level signal and the second voltage signal transmitted by the second voltage signal terminal VGH being a high level signal as an example.

The input sub-circuit 400 is turned on under the control of the turn-on signal transmitted by the signal input terminal Iput and the first clock signal transmitted by the first clock signal terminal CLK1 to output the second voltage signal received at the second voltage signal terminal VGH to the pull-up node PU, and to store the second voltage signal in the output sub-circuit 100.

The output sub-circuit 100 is turned on under the control of the voltage of the pull-up node PU to output the second clock signal received at the second clock signal terminal CLK2 to the signal output terminal Oput. In this case, a potential of the signal output terminal Oput is a low potential. That is, no scanning signal is output.

In addition, under the control of the voltage of the pull-up node PU and the second voltage signal transmitted by the second voltage signal terminal VGH, the second control sub-circuit 302 is turned on to output the first voltage signal received at the first voltage signal terminal VGL to the pull-down node PD, so as to pull down the potential of the pull-down node PD. At the same time, the fifth control sub-circuit 305 is turned on under the control of the turn-on signal input from the signal input terminal Iput to output the first voltage signal received at the first voltage signal terminal VGL to the pull-down node PD, so as to pull down the potential of the pull-down node PD. Thus, in the first phase S1, the potential of the pull-down node PD is a low potential.

The first control sub-circuit 301, the third control sub-circuit 303, the fourth control sub-circuit 304 and the pull-down sub-circuit 600 are all turned off.

For example, referring to FIGS. 4 and 6, in the first phase S1, the eighth transistor T8 is turned on under the control of the turn-on signal transmitted by the signal input terminal Iput, and the ninth transistor T9 is turned on under the control of the first clock signal transmitted by the first clock signal terminal CLK1. Thus, the eighth transistor T8 and the ninth transistor T9 output the second voltage signal received at the second voltage signal terminal VGH to the pull-up node PU, so that the potential of the pull-up node PU is a high potential.

The first capacitor C1 stores the potential of the pull-up node PU, and the first transistor T1 is turned on under the control of the voltage of the pull-up node PU to output the second clock signal received at the second clock signal terminal CLK2 to the signal output terminal Oput.

The fourth transistor T4 is turned on under the control of the second voltage signal transmitted by the second voltage signal terminal VGH to transmit the voltage of the pull-up node PU to the control electrode of the third transistor T3, so that the third transistor T3 is turned on to output the first voltage signal received at the first voltage signal terminal VGL to the pull-down node PD. The seventh transistor T7 is turned on under the control of the turn-on signal input from the signal input terminal put to output the first voltage signal received at the first voltage signal terminal VGL to the pull-down node PD. Thus, in the first phase S1, the potential of the pull-down node PD is a low potential.

The second transistor T2, the fifth transistor T5, the sixth transistor T6 and the tenth transistor T10 are turned off in the first phase S1.

In a second phase S2 (also referred to as an output phase):

the level of the first clock signal transmitted by the first clock signal terminal CLK1 is a low level, the level of the second clock signal transmitted by the second clock signal terminal CLK2 is a high level, the level of the third clock signal transmitted by the third clock signal terminal CLK3 is a low level. Take the first voltage signal transmitted by the first voltage signal terminal VGL being a low level signal and the second voltage signal transmitted by the second voltage signal terminal VGH being a high level signal as an example.

The pull-up node PU maintains the voltage thereof in the first phase S1, and the output sub-circuit 100 remains on under the control of the voltage of the pull-up node to output the second dock signal received at the second dock signal terminal CLK2 as the scanning signal to the signal output terminal Oput. Under the control of the voltage of the signal output terminal Oput, the first control sub-circuit 301 is turned on to output the first voltage signal received at the first voltage signal terminal VGL to the pull-down node PD.

In addition, under the control of the voltage of the pull-up node PU and the second voltage signal transmitted by the second voltage signal terminal VGH, the second control sub-circuit 302 remains on to output continuously the first voltage signal received at the first voltage signal terminal VGL to the pull-down node PD, so that the potential of the pull-down node PD remains at a low potential.

The input sub-circuit 400, the third control sub-circuit 303, the fourth control sub-circuit 304, the fifth control sub-circuit 305 and the pull-down sub-circuit 600 are all turned off.

For example, referring to FIGS. 4 and 6, in the second phase S2, the first capacitor C1 discharges to the pull-up node PU, and the pull-up node PU maintains at a high level potential. The first transistor T1 remains on under the control of the voltage of the pull-up node PU to output the second clock signal (at a high level in this case) received at the second clock signal terminal CLK2 as the scanning signal to the signal output terminal Oput. At the same time, the first capacitor C1 further raises the potential of the pull-up node PU through the bootstrap effect under an action of a high level voltage output from the signal output terminal Oput.

In addition, under the control of the high level voltage of the signal output terminal Oput, the second transistor T2 is turned on to output the first voltage signal received at the first voltage signal terminal VGL to the pull-down node PD.

The fourth transistor T4 is turned on under the control of the second voltage signal transmitted by the second voltage signal terminal VGH to transmit the voltage of the pull-up node PU to the control electrode of the third transistor T3, so that the third transistor T3 is turned on to output the first voltage signal received at the first voltage signal terminal VGL to the pull-down node PD. Thus, in the second phase S2, the potential of the pull-down node PD is a low potential.

The fifth transistor T5, the sixth transistor T6, the seventh transistor T7, the eighth transistor T8, the ninth transistor T9 and the tenth transistor T10 are turned off in the second phase S2.

In a third phase S3 (also referred to as a first reset phase):

the level of the first dock signal transmitted by the first clock signal terminal CLK1 is a low level, the level of the second clock signal transmitted by the second clock signal terminal CLK2 is a low level, and the level of the third clock signal transmitted by the third clock signal terminal CLK3 is a high level. Take the first voltage signal transmitted by the first voltage signal terminal VGL being a low level signal and the second voltage signal transmitted by the second voltage signal terminal VGH being a high level signal as an example.

Under the control of the third clock signal transmitted by the third clock signal terminal CLK3, the fourth control sub-circuit 304 is turned on to output the second voltage signal received at the second voltage signal terminal VGH to the pull-down node PD, and to store the second voltage signal in the energy storage sub-circuit 500, thereby pulling up the potential of the pull-down node PD.

Under the control of the voltage of the pull-down node PD, the third control sub-circuit 303 is turned on to output the first voltage signal received at the first voltage signal terminal VGL to the pull-up node PU, so as to reset the potential of the pull-up node PU. Under the control of the voltage of the pull-down node PD, the pull-down sub-circuit 600 is turned on to output the first voltage signal received at the first voltage signal terminal VGL to the signal output terminal Oput, so as to reset the potential of the signal output terminal Oput.

The input sub-circuit 400, the output sub-circuit 100, the first control sub-circuit 301, the second control sub-circuit 302 and the fifth control sub-circuit 305 are all turned off.

For example, referring to FIGS. 4 and 6, in the third phase S3, under the control of the third clock signal transmitted by the third clock signal terminal CLK3, the sixth transistor T6 is turned on to output the second voltage signal received at the second voltage signal terminal VGH to the pull-down node PD, and to store the second voltage signal in the third capacitor C3. In this case, the potential of the pull-down node PD is pulled up.

Under the control of the voltage of the pull-down node PD, the fifth transistor T5 is turned on to output the first voltage signal received at the first voltage signal terminal VGL to the pull-up node PU, thereby resetting the potential of the pull-up node PU. Under the control of the voltage of the pull-down node PD, the tenth transistor T10 is turned on to output the first voltage signal received at the first voltage signal terminal VGL to the signal output terminal Oput, so as to reset the potential of the signal output terminal Oput.

The first transistor T1, the second transistor T2, the third transistor T3, the seventh transistor T7, the eighth transistor T8 and the ninth transistor T9 are turned off in the third phase S3.

In a fourth phase S4 (also referred to as a second reset phase):

the level of the first clock signal transmitted by the first clock signal terminal CLK1 is a high level, the level of the second clock signal transmitted by the second clock signal terminal CLK2 is a low level, and the level of the third clock signal transmitted by the third clock signal terminal CLK3 is a low level. Take the first voltage signal transmitted by the first voltage signal terminal VGL being a low level signal and the second voltage signal transmitted by the second voltage signal terminal VGH being a high level signal as an example.

The energy storage sub-circuit 500 discharges to the pull-down node PD, so that the pull-down node PD remains the voltage thereof in the third phase S3. Under the control of the voltage of the pull-down node PD, the third control sub-circuit 303 remains on to output the first voltage signal received at the first voltage signal terminal VGL to the pull-up node PU, thereby resetting the potential of the pull-up node PU. The pull-down sub-circuit 600 remains on to output the first voltage signal received at the first voltage signal terminal VGL to the signal output terminal Oput, so as to reset the potential of the signal output terminal Oput.

The input sub-circuit 400, the output sub-circuit 100, the first control sub-circuit 301, the second control sub-circuit 302, the fourth control sub-circuit 304 and the fifth control sub-circuit 305 are all turned off.

For example, referring to FIGS. 4 and 6, the third capacitor C3 discharges to the pull-down node PD, and the pull-down node PD maintains the high level voltage in the third phase S3. Under the control of the voltage of the pull-down node PD, the fifth transistor T5 is turned on to output the first voltage signal received at the first voltage signal terminal VGL to the pull-up node PU, thereby resetting the potential of the pull-up node PU. Under the control of the voltage of the pull-down node PD, the tenth transistor T10 is turned on to output the first voltage signal received at the first voltage signal terminal VGL to the signal output terminal Oput, so as to reset the potential of the signal output terminal Oput.

The first transistor T1, the second transistor T2, the third transistor T3, the sixth transistor T6, the seventh transistor T7, the eighth transistor T8 and the ninth transistor T9 are turned off in the fourth phase S4.

In a fifth phase S5 (also referred to as a third reset phase):

the level of the first dock signal transmitted by the first clock signal terminal CLK1 is a low level, the level of the second clock signal transmitted by the second clock signal terminal CLK2 is a high level, and the level of the third clock signal transmitted by the third clock signal terminal CLK3 is a low level. Take the first voltage signal transmitted by the first voltage signal terminal VGL being a low level signal and the second voltage signal transmitted by the second voltage signal terminal VGH being a high level signal as an example.

The coupling sub-circuit 200 couples the voltage of the pull-down node PD through the second clock signal received at the second clock signal terminal CLK2 to stably control the potential of the pull-down node PD, thereby avoiding a stability reduction of the pull-down node PD caused by the influence of the peripheral circuits (e.g., the peripheral parasitic capacitors). Under the control of the voltage of the pull-down node PD, the third control sub-circuit 303 remains on to output a voltage at the first voltage signal terminal VGL to the pull-up node PU, and the pull-down sub-circuit 600 remains on to output the voltage at the first voltage signal terminal VGL to the signal output terminal Oput, so as to perform a continuous noise reduction on the potential of the pull-up node PU and the potential of the signal output terminal Oput.

For example, referring to FIGS. 4 and 6, the high level voltage of the second clock signal terminal CLK2 couples the voltage of the pull-down node PD through the second capacitor C2, so as to raise the potential of the pull-down node PD, thereby ensuring that the pull-down node PD remains at a high level voltage, and avoiding a potential drop of the pull-down node PD caused by the influence of the peripheral circuits, so as to ensure the output stability. Under a control of a high level voltage of the pull-down node PD, the fifth transistor T5 remains on to output the first voltage signal received at the first voltage signal terminal VGL to the pull-up node PU, and the tenth transistor T10 remains on to output the first voltage signal received at the first voltage signal terminal VGL to the signal output terminal Oput.

The first transistor T1, the second transistor T2, the third transistor T3, the fourth transistor T4, the sixth transistor T6, the seventh transistor T7, the eighth transistor T8 and the ninth transistor T9 are turned off in the fifth phase S5.

After the fifth phase S5 and before an arrival of a next image frame, processes of the third phase S3, the fourth phase S4 and the fifth phase S5 are periodically repeated.

It will be noted that the transistors in the embodiments of the present disclosure may be enhancement transistors or depletion transistors. The first electrodes of the above transistors may be sources and the second electrodes thereof may be drains, or the first electrodes of the above transistors may be drains and the second electrodes thereof may be sources, which is not limited in the embodiments of the present disclosure.

In the above embodiments of the present disclosure, turn-on and turn-off (on and off) processes of the transistors are all described by taking an example in which all of the transistors are N-type transistors. In the embodiments of the present disclosure, the transistors may also be of P-type. In a case where all of the transistors are of P-type, all control signals need to be inverted.

The above descriptions are only specific implementations of the present disclosure, but the protection scope of the present disclosure is not limited thereto. Changes or replacements any person skilled in the art could conceive of within the technical scope of the present disclosure shall be included in the protection scope of the present disclosure. Therefore, the protection scope of the present disclosure shall be subject to the protection scope of the claims.

1. A shift register, comprising an output sub-circuit and a coupling sub-circuit, wherein
the output sub-circuit is coupled to a second clock signal terminal, a pull-up node and a signal output terminal, and the output sub-circuit is configured to output a second clock signal received at the second clock signal terminal to the signal output terminal under a control of a voltage of the pull-up node; and
the coupling sub-circuit is coupled to the second clock signal terminal and a pull-down node, and the coupling sub-circuit is configured to couple a voltage of the pull-down node through the second clock signal received at the second clock signal terminal.

2. The shift register according to claim 1, wherein
the output sub-circuit includes a first transistor and a first capacitor; a control electrode of the first transistor is coupled to the pull-up node, a first electrode of the first transistor is coupled to the second clock signal terminal, and a second electrode of the first transistor is coupled to the signal output terminal; a first electrode of the first capacitor is coupled to the pull-up node, and a second electrode of the first capacitor is coupled to the signal output terminal; and
the coupling sub-circuit includes a second capacitor; a first electrode of the second capacitor is coupled to the pull-down node, and a second electrode of the second capacitor is coupled to the second clock signal terminal.

3. The shift register according to claim 1, further comprising a first control sub-circuit;
the first control sub-circuit being coupled to the signal output terminal, a first voltage signal terminal and the pull-down node, and the first control sub-circuit being configured to output a first voltage signal received at the first voltage signal terminal to the pull-down node under a control of a voltage of the signal output terminal.

4. The shift register according to claim 3, wherein the first control sub-circuit includes a second transistor; a control electrode of the second transistor is coupled to the signal output terminal, a first electrode of the second transistor is coupled to the first voltage signal terminal, and a second electrode of the second transistor is coupled to the pull-down node.

5. The shift register according to claim 1, further comprising a second control sub-circuit, a third control sub-circuit, a fourth control sub-circuit and an energy storage sub-circuit, wherein
the second control sub-circuit is coupled to the pull-up node, a first voltage signal terminal and the pull-down node, and the second control sub-circuit is configured to output a first voltage signal received at the first voltage signal terminal to the pull-down node under the control of the voltage of the pull-up node;
the third control sub-circuit is coupled to the pull-up node, the pull-down node and the first voltage signal terminal, and the third control sub-circuit is configured to output the first voltage signal received at the first voltage signal terminal to the pull-up node under the control of the voltage of the pull-down node;
the fourth control sub-circuit is coupled to a third clock signal terminal, a second voltage signal terminal and the pull-down node, and the fourth control sub-circuit is configured to output a second voltage signal received at the second voltage signal terminal to the pull-down node in response to a third clock signal received at the third voltage signal terminal; and
the energy storage sub-circuit is coupled to the pull-down node and the first voltage signal terminal, and the energy storage sub-circuit is configured to perform charging and discharging under the control of the voltage of the pull-down node.

6. The shift register according to claim 5, wherein
the second control sub-circuit includes a third transistor; a control electrode of the third transistor is coupled to the pull-up node, a first electrode of the third transistor is coupled to the first voltage signal terminal, and a second electrode of the third transistor is coupled to the pull-down node;
the third control sub-circuit includes a fifth transistor; a control electrode of the fifth transistor is coupled to the pull-down node, a first electrode of the fifth transistor is coupled to the first voltage signal terminal, and a second electrode of the fifth transistor is coupled to the pull-up node;
the fourth control sub-circuit includes a sixth transistor; a control electrode of the sixth transistor is coupled to the third clock signal terminal, a first electrode of the sixth transistor is coupled to the second voltage signal terminal, and a second electrode of the sixth transistor is coupled to the pull-down node; and
the energy storage sub-circuit includes a third capacitor; a first electrode of the third capacitor is coupled to the pull-down node, and a second electrode of the third capacitor is coupled to the first voltage signal terminal.

7. The shift register according to claim 5, further comprising a fifth control sub-circuit;
the fifth control sub-circuit being coupled to a signal input terminal, the first voltage signal terminal and the pull-down node; the fifth control sub-circuit being configured to output the first voltage signal received at the first voltage signal terminal to the pull-down node in response to a turn-on signal received at the signal input terminal.

8. The shift register according to claim 7, wherein the fifth control sub-circuit includes a seventh transistor; a control electrode of the seventh transistor is coupled to the signal input terminal, a first electrode of the seventh transistor is coupled to the first voltage signal terminal, and a second electrode of the seventh transistor is coupled to the pull-down node.

9. The shift register according to claim 1, further comprising an input sub-circuit and a pull-down sub-circuit, wherein
the input sub-circuit is coupled to a signal input terminal, a second voltage signal terminal and the pull-up node, and the input sub-circuit is configured to output a second voltage signal received at the second voltage signal terminal to the pull-up node in response to a turn-on signal received at the signal input terminal;
the pull-down sub-circuit is coupled to the pull-down node, a first voltage signal terminal and the signal output terminal, and the pull-down sub-circuit is configured to output a first voltage signal received at the first voltage signal terminal to the signal output terminal under the control of the voltage of the pull-down node.

10. The shift register according to claim 9, wherein
the input sub-circuit includes an eighth transistor; a control electrode of the eighth transistor is coupled to the signal input terminal, a first electrode of the eighth transistor is coupled to the second voltage signal terminal, and a second electrode of the eighth transistor is coupled to the pull-up node;
the pull-down sub-circuit includes a tenth transistor; a control electrode of the tenth transistor is coupled to the pull-down node, a first electrode of the tenth transistor is coupled to the first voltage signal terminal, and a second electrode of the tenth transistor is coupled to the signal output terminal.

11. The shift register according to claim 1, further comprising a first control sub-circuit, a second control sub-circuit, a third control sub-circuit, a fourth control sub-circuit, an energy storage sub-circuit, a fifth control sub-circuit, an input sub-circuit and a pull-down sub-circuit, wherein
the output sub-circuit includes a first transistor and a first capacitor; the coupling sub-circuit includes a second capacitor; the first control sub-circuit includes a second transistor; the second control sub-circuit includes a third transistor and a fourth transistor; the third control sub-circuit includes a fifth transistor; the fourth control sub-circuit includes a sixth transistor; the energy storage sub-circuit includes a third capacitor; the fifth control sub-circuit includes a seventh transistor; the input sub-circuit includes an eighth transistor and a ninth transistor; the pull-down sub-circuit includes a tenth transistor;
a control electrode of the first transistor is coupled to the pull-up node, a first electrode of the first transistor is coupled to the second clock signal terminal, and a second electrode of the first transistor is coupled to the signal output terminal; a first electrode of the first capacitor is coupled to the pull-up node, and a second electrode of the first capacitor is coupled to the signal output terminal;
a first electrode of the second capacitor is coupled to the pull-down node, and a second electrode of the second capacitor is coupled to the second clock signal terminal;
a control electrode of the second transistor is coupled to the signal output terminal, a first electrode of the second transistor is coupled to a first voltage signal terminal, and a second electrode of the second transistor is coupled to the pull-down node;
a control electrode of the fourth transistor is coupled to a second voltage signal terminal, a first electrode of the fourth transistor is coupled to the pull-up node, and a second electrode of the fourth transistor is coupled to a control electrode of the third transistor; a first electrode of the third transistor is coupled to the first voltage signal terminal, and a second electrode of the third transistor is coupled to the pull-down node;
a control electrode of the fifth transistor is coupled to the pull-down node, a first electrode of the fifth transistor is coupled to the first voltage signal terminal, and a second electrode of the fifth transistor is coupled to the pull-up node;
a control electrode of the sixth transistor is coupled to a third clock signal terminal, a first electrode of the sixth transistor is coupled to the second voltage signal terminal, and a second electrode of the sixth transistor is coupled to the pull-down node;
a first electrode of the third capacitor is coupled to the pull-down node, and a second electrode of the third capacitor is coupled to the first voltage signal terminal;
a control electrode of the seventh transistor is coupled to a signal input terminal, a first electrode of the seventh transistor is coupled to the first voltage signal terminal, and a second electrode of the seventh transistor is coupled to the pull-down node;
a control electrode of the eighth transistor is coupled to the signal input terminal, a first electrode of the eighth transistor is coupled to the second voltage signal terminal, and a second electrode of the eighth transistor is coupled to a first electrode of the ninth transistor; a control electrode of the ninth transistor is coupled to a first clock signal terminal, and a second electrode of the ninth transistor is coupled to the pull-up node; and
a control electrode of the tenth transistor is coupled to the pull-down node, a first electrode of the tenth transistor is coupled to the first voltage signal terminal, and a second electrode of the tenth transistor is coupled to the signal output terminal.

12. A gate driving circuit, comprising N stages of cascaded shift registers according to claim 1.

13. A display apparatus, comprising the gate driving circuit according to claim 12.

14. A method for driving the shift register according to claim 1, comprising:
in an output phase, the output sub-circuit being turned on under the control of the voltage of the pull-up node to output the second clock signal received at the second clock signal terminal as a scanning signal to the signal output terminal; and
after the output phase, in a phase in which a voltage of the second clock signal is same as a voltage of the second clock signal in the output phase, the coupling sub-circuit coupling the voltage of the pull-down node through the second clock signal.

15. The shift register according to claim 1, further comprising a second control sub-circuit, a third control sub-circuit, a fourth control sub-circuit and an energy storage sub-circuit, wherein
the second control sub-circuit is coupled to the pull-up node, a first voltage signal terminal, a second voltage signal terminal and the pull-down node, and the second control sub-circuit is configured to output a first voltage signal received at the first voltage signal terminal to the pull-down node in response to the voltage of the pull-up node and a second voltage signal received at the second voltage signal terminal;
the third control sub-circuit is coupled to the pull-up node, the pull-down node and the first voltage signal terminal, and the third control sub-circuit is configured to output the first voltage signal received at the first voltage signal terminal to the pull-up node under the control of the voltage of the pull-down node;
the fourth control sub-circuit is coupled to a third clock signal terminal, the second voltage signal terminal and the pull-down node, and the fourth control sub-circuit is configured to output the second voltage signal received at the second voltage signal terminal to the pull-down node in response to a third clock signal received at the third voltage signal terminal; and
the energy storage sub-circuit is coupled to the pull-down node and the first voltage signal terminal, and the energy storage sub-circuit is configured to perform charging and discharging under the control of the voltage of the pull-down node.

16. The shift register according to claim 15, wherein
the second control sub-circuit includes a third transistor and a fourth transistor; a control electrode of the fourth transistor is coupled to the second voltage signal terminal, a first electrode of the fourth transistor is coupled to the pull-up node, a second electrode of the fourth transistor is coupled to a control electrode of the third transistor, a first electrode of the third transistor is coupled to the first voltage signal terminal, and a second electrode of the third transistor is coupled to the pull-down node;
the third control sub-circuit includes a fifth transistor; a control electrode of the fifth transistor is coupled to the pull-down node, a first electrode of the fifth transistor is coupled to the first voltage signal terminal, and a second electrode of the fifth transistor is coupled to the pull-up node;
the fourth control sub-circuit includes a sixth transistor; a control electrode of the sixth transistor is coupled to the third clock signal terminal, a first electrode of the sixth transistor is coupled to the second voltage signal terminal, and a second electrode of the sixth transistor is coupled to the pull-down node; and
the energy storage sub-circuit includes a third capacitor; a first electrode of the third capacitor is coupled to the pull-down node, and a second electrode of the third capacitor is coupled to the first voltage signal terminal.

17. The shift register according to claim 15, further comprising a fifth control sub-circuit;
the fifth control sub-circuit being coupled to a signal input terminal, the first voltage signal terminal and the pull-down node; the fifth control sub-circuit being configured to output the first voltage signal received at the first voltage signal terminal to the pull-down node in response to a turn-on signal received at the signal input terminal.

18. The shift register according to claim 1, further comprising an input sub-circuit and a pull-down sub-circuit, wherein
the input sub-circuit is coupled to a signal input terminal, a second voltage signal terminal, a first clock signal terminal and the pull-up node, and the input sub-circuit is configured to output a second voltage signal received at the second voltage signal terminal to the pull-up node in response to a turn-on signal received at the signal input terminal and a first clock signal received at the first clock signal terminal; and
the pull-down sub-circuit is coupled to the pull-down node, a first voltage signal terminal and the signal output terminal, and the pull-down sub-circuit is configured to output a first voltage signal received at the first voltage signal terminal to the signal output terminal under the control of the voltage of the pull-down node.

19. The shift register according to claim 18, wherein
the input sub-circuit includes an eighth transistor and a ninth transistor; a control electrode of the eighth transistor is coupled to the signal input terminal, a first electrode of the eighth transistor is coupled to the second voltage signal terminal, a second electrode of the eighth transistor is coupled to a first electrode of the ninth transistor, a control electrode of the ninth transistor is coupled to the first clock signal terminal, and a second electrode of the ninth transistor is coupled to the pull-up node; and
the pull-down sub-circuit includes a tenth transistor; a control electrode of the tenth transistor is coupled to the pull-down node, a first electrode of the tenth transistor is coupled to the first voltage signal terminal, and a second electrode of the tenth transistor is coupled to the signal output terminal.
